(19) United States
(12) Patent Application Publication
(10) Pub. No.: US 2015/0377517 A1
(43) Pub. Date: Dec. 31, 2015

(54) SOLAR ENERGY COLLECTION APPARATUS CONTAINING A POROUS METAL ABSORBER PLATE

(71) Applicant: James H. Bushong, JR., Collegeville, PA (US)

(72) Inventor: James H. Bushong, JR., Collegeville, PA (US)

(21) Appl. No.: 13/790,210

(22) Filed: Mar. 8, 2013

Related U.S. Application Data
(60) Provisional application No. 61/795,155, filed on Oct. 11, 2012.

(51) Int. Cl. F24J 2/28; F24J 2/05; H01L 31/058; F24J 2/08

(52) U.S. Cl. CPC F24J 2/28; F24J 2/085; F24J 2/05; H01L 31/058

(57) ABSTRACT

The present invention offers improved absorber plates for solar energy collectors, improved cover glazings for solar energy collectors, improved concentrating solar energy collectors, and solar energy collection methods that use one or more of the improved solar energy collectors for useful residential, commercial, and industrial applications. The improved absorber plate solar energy collectors utilize a porous metal to improve solar radiant absorption collection and utilization, the improved concentrating solar energy collectors are Fresnel lens faced ducts of various geometries that enable efficient axial length solar energy collection, and the improved cover glazings utilize transparent front and back faces with other improvements to enable increased solar radiant energy collection per unit front face cover area of solar collector.

### CROSS REFERENCE TO RELATED APPLICATIONS

This application claims the benefit of provisional application Ser. No. 61/795,155 filed Oct. 11, 2012 by the inventor herein and entitled Apparatus and Methods for Solar Thermal Energy Systems.

### FIELD OF THE INVENTION

The present invention relates generally to apparatus and methods of improving solar energy collection and utilization. The invention offers improved solar energy collectors and utilization methods that can be especially useful for improving the energy efficiency or the heating performance or a combination of energy efficiency and heating performance of heat pumps or other interior building heating systems and hot water systems. The improved solar energy collectors and utilization methods can also be useful as a source of renewable energy for energy intensive industrial processes such as chemical production processes and for a variety of other residential, commercial, and industrial energy applications.

### BACKGROUND ART

Solar thermal energy collection is used commercially for hot water heating and space heating. Typically a flat plate solar collector is utilized to absorb the solar energy onto a highly conductive flat sheet-metal plate, and the solar energy is transferred from the flat plate to tubes (typically copper) containing water or other heat transfer fluid circulating through the tubes, and the heat is exchanged for heating water. Other type of solar collectors for thermal energy systems include evacuated glass tubes, wherein the heat transfer fluid-containing tubes are integrated into the evacuated glass tubes to improve radiant heat absorption efficiency by eliminating convective heat losses within the evacuated glass tubes. Evacuated tube collectors enable a higher temperature to be achieved compared to conventional flat plate collectors, but at some loss in heat transfer area relative to a flat plate collector of the same overall system physical dimensions.

Heat pumps are a common source of residential and industrial building heating. Typically a refrigerant circulating within the heat pump system is used to extract heat from ambient air, and the refrigerant undergoes evaporation, compression, and condensation to provide heat to the interior of a home or building. The heat pump is able to raise the air temperature within the home or building based on the thermodynamics of the expansion/compression/condensation process and the source air temperature to the heat pump. However it is well known that below certain ambient temperatures, a heat pump can no longer heat the ambient air to a level sufficient for a comfortable interior temperature; typically in these cases an electrical resistance heating unit must provide supplemental heating. The electrical resistance heating is very energy intensive and therefore expensive to operate as well as a major consumer of energy. At some other ranges of ambient temperatures, a heat pump can function without the electrical resistance heating but only at interior thermostat temperature settings that some people would find lower than desirable. Due to the thermodynamic laws, the heat pump is limited to a certain ability to raise the interior air temperature in the home or building compared to the outside ambient air temperature. The difference in outside ambient air temperature compared to the interior air temperature is the “delta Temperature”; the lower the ambient temperature, the lower the temperature that the air-source heat pump is capable of providing to the interior home or building. The heat pump energy efficiency also suffers when the outside air temperature is substantially lower than the desired interior air temperature; this is best expressed as the “Coefficient of Performance” (COP) which measures the amount of heat output per unit of input electrical energy to the heat pump compressor. The Coefficient of Performance of the heat pump can vary from as much as 3 to 4 units of energy output per unit of electrical input to the heat pump compressor on mild days around 10° C., to as low as 1 unit of energy output per unit of electrical input to the heat pump compressor on a cold day around-18° C.

Recent developments in improving heat pumps relate to geothermal heat pumps. These systems use the ground as a heat source, taking advantage of warmer temperatures below the ground surface to boost efficiency (improve the COP) of the heat pump by providing a source temperature to the heat pump that is higher than the ambient air temperature. However, the geothermal heat pumps require significant initial investment and usually involve substantial and expensive drilling into the ground. Further limitations of geothermal heat pumps include soil-specific performance/problems with certain soil conditions, corrosion of pipes in the ground, and possibilities of ground-water contamination from the heat-transfer fluid circulating in the underground pipes.

### SUMMARY OF INVENTION

The present invention relates generally to apparatus and methods of improving solar energy collection and utilization. The invention offers improved solar energy collectors and utilization methods that can be especially useful for improving the energy efficiency or the heating performance or a combination of energy efficiency and heating performance of heat pumps or other interior building heating systems and hot water systems. The improved solar energy collectors and utilization methods can also be useful as a source of renewable energy for energy intensive industrial processes such as chemical production processes and for a variety of other residential, commercial, and industrial energy applications.

The present invention offers improved absorber plates for solar energy collectors, improved cover glazings for solar energy collectors, improved concentrating solar energy collectors, and systems that use one or more of the improved solar energy collectors for useful residential, commercial, and industrial applications.

The improved absorber plate solar energy collection apparatus of the present invention are characterized by utilizing a porous metal absorber plate that has an open lattice-work of air pockets and channels within strands of metal, and maintains sufficient inter-connectivity of metal strands to remain a singular object. The porosity of the porous metal absorber plate can range from about 25% to about 98%, or from about 50% to about 98%, or from about 60% to about 98%; any of these ranges of porosity are far higher than conventional metal absorber plates utilized in solar collectors that have essentially 0% porosity. The porosity of the metal absorber plate can be selected such that a working fluid can be passed directly through the absorber plate instead of conventional technology wherein working fluid is passed through pipes that are attached to a non-porous metal absorber plate. As used herein, the term working fluid refers to any liquid, vapor, or solid that solar energy can beneficially be imparted to for any purpose.

The improved cover glazings of the present invention are characterized by utilizing transparent front and back faces such that solar radiant energy that misses the front face can effectively be reflected onto the back face, enabling up to twice the solar radiant energy hitting the collector per unit area of the front face of the solar collector. The convention used herein is to label the front cover glazing as the cover glazing that is closer to the sun compared to the back cover glazing. The improved cover glazings can further have evacuated or inert gas filled gaps between the front and/or back faces to substantially reduce convective heat transfer losses back to the environment. Additionally, the improved cover glazings can have duct work or similar light transmitting surfaces installed along the sides of the collector housing; sunlight that misses the front face of the solar collector can enter these side-ducts, where it is optically guided to a reflecting plate such that additional solar radiant energy is collected and then reflected on the back face of the solar collector. The improved cover glazings are preferably used with the improved absorber plate solar collectors of the present invention, forming an air or liquid-tight housing around the porous metal absorber plate of the present invention with appropriate fittings to allow a working fluid to enter and exit the porous metal absorber plate, and allowing for reflected light to hit the back transparent face of the collector housing to increase the solar energy absorption per unit of front-face solar collector area.

The improved solar energy concentrating apparatus of the present invention are characterized by utilizing Fresnel refracting lenses as part of an outer duct that houses a working fluid either within the duct or houses an inner conduit with working fluid inside of the inner conduit. All or a portion of the outer duct that faces the sun can be Fresnel refracting lenses, either integrally built into the duct or as inserts at various locations along the duct. The Fresnel lenses may be square, concave, hemispheres, or cylinders for example. An inner conduit containing a working fluid can be placed at a location inside the outer duct such that the concentration factor (defined as the Area of Fresnel refractor lens concentrator/Area of concentrated light at point of contact with the inner conduit) of the Fresnel lens is sufficiently high to provide favorable temperature increase of the inner conduit and the working fluid therein. This novel means of using Fresnel refracting lenses can be seen to be useful for any outdoor applications wherein heating and/or maintaining temperatures within ductwork is useful, and at least 1 side of the duct accepts sufficient sunlight. The ductwork with Fresnel refracting lenses may further be enhanced for useful solar energy collection by having all or a portion of the side or back walls of the duct made in the geometric form of a parabolic trough solar light collector and appropriate solar reflective material in order to capture and refocus any stray light rays from the Fresnel refractor that do not hit a target such as e.g. an inner conduit containing a working fluid on the first pass. Optionally solar-reflective film can be shaped into a parabolic trough shape and placed within the duct, such that any stray light from the Fresnel refractive lens is re-focused onto a target such as e.g. an inner conduit(s) traversing through the duct. Optionally some portion or all of the side or back walls of the Fresnel refractor duct may be a sunlight absorbing material such as black plastic or other black materials or black coating materials on a substrate, to capture any stray light rays that do not hit a target such as e.g. an inner conduit traversing through the duct; this would enable any stray light rays to serve a useful purpose of heating the ductwork to help maintain higher temperatures inside the duct.

The porous metal absorber plate of the present invention has an open lattice-work of air pockets and channels, to enable sunlight to penetrate deeper within the absorber plate and at a much faster rate compared to solar radiant energy conducting through a conventional solid metal plate. All sunlight rays that penetrate into the open lattice-work matrix without obstruction reach the point of impact in the depth of the porous metal absorber plate at nearly the speed of light, compared to solar light first being converted to heat upon impact of a conventional non-porous flat plate and then the heat traversing the depth of the absorber plate via heat conduction as occurs in a standard non-porous flat absorber plate. The open lattice-work of the porous metal absorber plate can capture more sun light rays per equivalent geometric perimeter area of a conventional non-porous flat absorber plate due to less reflective light escaping. Light rays that penetrate within the depth of the open lattice-work of the porous metal absorber plate of the present invention have the ability to refract and reflect within the lattice-work matrix, and can be captured within the 3-dimensional tortuous porous lattice of metal, as opposed to a conventional non-porous flat absorber plate wherein light rays are either absorbed or reflected at the thin surface layer only. The porous metal absorber plate of the present invention is therefore observed to possess high absorptive capacity for solar energy by possessing much greater light-penetrating depth than conventional non-porous sheet metal absorber plates, and a high rate of absorption of solar energy due to open porous lattice enabling light ray penetration into the depths of the porous metal absorber plate at nearly the speed of light, as well as faster heat transfer rates with the superior heat transfer method of convection within the porous metal lattice compared to conduction between a flat piece of sheet metal with e.g. pipes welded underneath, and reduced light escaping via improved refraction and reflection within the tortuous metal lattice for light rays that enter in the pores and achieve depth penetration within the porous metal lattice. The improved absorber plate of the present invention can thus offer high performance without expensive “selective coatings” that prior art has employed to improve absorption of sunlight and reduce light reflections. The improved absorber plate of the present invention can utilize standard coating methods such as appropriate matte black paint, or anodizing to make a black surface, and provide a high performance solar collector. However, a selective coating (such as electroplated black chrome) can be utilized on the porous metal absorber plate of the present invention. In some examples, only a portion of the porous metal absorber plate is coated only to a certain depth with a sunlight absorbing paint or sunlight absorbing electroplating coating or other means of coating to enable high absorption of sunlight. The depth to apply the sunlight absorbing coating is selected such that virtually all of the incident solar light rays will have either already been absorbed or reflected; after this depth is reached there is very little or no additional benefit for utilizing a sunlight absorbing coating. If a coating is placed on the porous metal, a controlled-depth coating can be achieved either by a manufacturing process that enables the coating to penetrate only to a certain depth, or to use for example 2 different porous metal plates such as a top plate closest to the sun that has coating throughout, and has a depth in accordance with the expected sun light ray penetration, and a bottom plate that has no coating. When 2 porous metal plates are utilized, a molded form on both plates that enables e.g. pipes or tubes to be inserted between the porous metal plates can be utilized. The bottom porous metal plate may have a different porosity than the top plate. Additionally, the bottom metal plate may be non-porous. In addition to these novel advantages, the porous metal absorber plate collector of the present invention easily enables molded shapes within the porous metal matrix; in this mariner, pipes containing a working fluid can have their “space” pre-molded into the porous metal absorber plate collector when the porous metal absorber plate collector is fabricated. This enables these pipes to be inserted directly into the porous metal absorber plate collector, for substantial metal (of the porous plate) to metal (of the pipe containing the working fluid) contact without welding. Typical flat plate collectors have the working fluid-containing pipes welded to the bottom of the flat plate; conduction occurs over a limited area at the pipe welds and where the part of the pipe contacts the flat plate. Pre-molded spaces that can be incorporated into the porous metal absorber plate solar energy collector of the present invention can offer greater contact area for higher heat transfer rates; more of the radial surfaces of the pipes can be in contact with metal from the porous metal absorber plate collector compared to the limited welded area and limited radial area contact with conventional flat plate collectors and the pipes traversing underneath the conventional flat plate absorber. The porous metal plate enables convection throughout the lattice for high heat transfer rates and more uniform temperature distribution throughout the porous metal plate compared to typical non-porous flat plate collectors. It can also beneficial for the metal absorber plate to be free of coatings, in order to maintain the high thermal conductivity (k) coefficients of e.g. copper or aluminum of the porous metal absorber plate of the present invention, especially since any coating is likely to reduce the thermal conductivity coefficient (k) compared to the extraordinarily high thermal conductivity of bare copper or aluminum. An ideal way to achieve the high solar light absorption associated with black surfaces but without using a coating on the porous metal plate of the present invention solar collector is to use a working fluid that is dyed black. It is preferred that the black dye be added to a level that enables the working fluid to still be semi-transparent to allow light to penetrate a significant depth of the porous metal plate, yet be sufficiently black to provide high solar light absorption. Utilizing a black-dyed working fluid is possible because the working fluid can be passed directly throughout the porous metal absorber plate, with sun light penetrating within the porous metal. The combination of directly absorbed solar radiation to the black-dyed working fluid, the high contact area between the high surface area, high thermal conductivity porous metal absorber plate, and the beneficial convective heat transfer process of the working fluid traversing through the porous metal lattice absorber plate offers an outstanding improvement compared to the conventional flat plate absorber solar collector. The convection heat transfer rate of the fluid passing through the porous metal absorber plate will be superior to the conduction heat transfer rate between the conventional absorber plate and e.g. pipes that traverse along the conventional absorber plate and then require these pipes to transfer this heat to a fluid traversing inside them. The high absorption of solar radiant energy combined with high heat transfer rate made possible by passing the fluid through the porous metal absorber plate enables greater extraction of the available solar radiant energy, and greater utilization of the available solar thermal energy by the working fluid. A further advantage of passing the flow through the porous metal absorber plate is that a greater volume of working fluid can be held in the collector per unit area of collector compared to conventional limited number of pipes and working fluid volume per unit area of collector in a conventional flat plate or evacuated tube collector. By enabling a greater volume of working fluid per unit area of collector, the contact time in the collector (working fluid volume in the solar collector divided by working fluid flow rate) can be increased, to allow the working fluid to achieve a higher temperature and/or to enable a working fluid to phase-change from a liquid to a gas and/or to enable more working fluid to be heated per unit area of solar energy collector, and thereby enable more useful thermodynamic work to be extracted from the working fluid. The porous metal absorber plates of the present invention can be used in flat-plate type solar collectors, evacuated tube type solar collectors, or any other form or type of solar energy collection apparatus.

The cover glazings of the present invention can be glass or plastic cover sheet(s). A preferred embodiment is to utilize transparent front and back glazings, enabling up to double the available unit area of solar energy collection compared to a solar collector that has only a transparent front-cover glazing. In the present invention, stray sunlight rays that miss the front face of the collector can be reflected to hit the transparent back face of the collector, where the sunlight can then effectively be absorbed as solar energy, preferably by the porous metal absorber plate of the present invention. In addition to the benefit of allowing for up to double the solar energy impacting the solar energy collector per unit of front-cover face area compared to a transparent front-cover face only collector, the solar energy absorbed from the back cover can reduce the temperature difference between the front and back faces of the collector. By reducing this temperature gradient, heat losses back to the environment can be reduced. For instances where the cover glazings are made of plastic, the sidewalls of the glazing cover(s) are preferably made from the same plastic, so that a 1 or 2 piece structure that houses the absorber plate can be manufactured by injection molding, thermoforming, casting, or any other method commonly used to manufacture plastic housings. A further improved glazing for the front and/or back covers is to utilize a two-walled cover glazing with a gap in between the walls that is either evacuated or filled with an inert gas. Although this can be accomplished using glass with elastomeric seals (as with traditional double pane glass windows), a preferred embodiment is to use thermoplastics that can have an evacuated gap formed during the manufacturing process. By utilizing thermoplastics in this way, there are no seals to wear out, and the evacuated gap can remain a permanent part of the covers. This evacuated gap enables the advantage of substantially reduced or practically eliminated convection between the absorber plate and the outer cover glazing. The evacuated cover acts as a highly efficient dual cover; the face closest to the sun acting as the outer cover, and the evacuated space within the insert acting as a barrier to substantially reduce convective heat transfer losses from the absorber plate back to the environment, and the face closest to the absorber plate acting as an additional cover. Alternatively the metal absorber plate can be housed in a single front face glazing and single back face glazing, and a separate evacuated or inert-gas filled glazing in a shape to match the absorber plate can be inserted on top of the single front face glazing housing the metal absorber plate, or behind the single back face glazing housing the metal absorber plate, or there can be evacuated or inert-gas filled glazings inserted both on top of the front face and behind the back face of the solar collector. Utilizing evacuated or inert-filled gas glazings that are inserted on the top and/or bottom of a simple single front and back cover glazing/housing for the absorber plate allows for easy change-out of the inserts, thus enabling these additional glazings to be easily replaceable parts. These novel methods of using evacuated or inert-gas filled glazings enables the flat plate collector to possess similar advantage of evacuated tubes, while eliminating the disadvantages of evacuated tubes of reduced absorption area compared to flat plate collectors. When plastics are used for the inert-gas filled or evacuated glazings of the present invention, this represents another advantage of increased durability compared to conventional fragile evacuated tubes made of glass. In further examples of the glazings of the present invention, duct work or similar light transmitting surfaces can be installed along the sides of the collector glazing/housing; sunlight that misses the front face of the solar collector can enter these side-ducts, where it is guided to a reflecting plate such that additional solar radiant energy is collected and then reflected on the back face of the solar collector. These side ducts with light guiding and reflection can eliminate having to utilize a separate reflector plate; the reflector plate in this embodiment is seen to be a part of the solar collector. Although a separate reflector plate can be used with the solar collectors of the present invention, it is preferred that duct work or similar light transmitting surfaces, with light guiding to an integrated reflector plate, to all be attached to the solar collector; this can reduce the total footprint of the collector and reflector plate system, and enable more precise light reflection to the back cover glazing. For any of the porous metal plate collector embodiments of the present invention, the transparent or translucent cover sheets of the present invention can advantageously be utilized to reduce heat losses, and to serve as an air or liquid tight housing around the porous metal absorber plate.

The Fresnel lens faced ducts of the present invention enables the advantage of achieving higher temperatures than flat plate-type solar collectors, by concentrating the radiant solar energy onto the working fluid traversing within the Fresnel lens faced duct. Higher temperatures can enable more useful thermodynamic work extracted from the available solar radiant energy, as most heat transfer processes utilize temperature differences between the heat source (e.g. the working fluid) and the heat sink (the area upon which to apply heat); greater temperature differences enable greater driving force for more efficient heat transfer. Additionally, higher temperatures achieved within the Fresnel lens faced duct of the present invention enable greater flexibility for achieving phase-change, such as e.g. vaporizing a liquid to a gas. Phase changes can be extremely useful for e.g. heat transfer; when the gas is condensed back to a liquid it can release a substantial amount of heat energy to the heat sink. Additionally, the Fresnel lens faced duct of the present invention is very useful for maintaining or even increasing the temperature of a working fluid along axial lengths within the duct. As used herein, the term axial length refers to the length axis of the duct; for example if a duct of the present invention is 1 meter long and 100 mm diameter, the term axial length refers to the 1 meter long axis. It is well known that axial length heat losses can be proportional to the length-longer axial length distances typically result in more heat losses. Heat losses are generally encountered in working fluids traversing axial lengths unless a separate source of heat such as electrical heat tracing along the axial length is utilized. The Fresnel lens faced duct of the present invention can enable minimal heat losses along axial lengths, or even no heat losses to maintain temperature along axial lengths, or even a gain in thermal energy to achieve higher working fluid temperature along axial lengths within the duct.

One example of a useful application of the present invention is to offer a system that can raise the source temperature to the heat pump outdoor coil region above the normal ambient source air temperature to the conventional heat pump outdoor coil region. The increased source temperature to the heat pump coil region is accomplished by utilizing the system to collect solar heat during daylight hours, and transfer this heat directly to the heat pump coil, and/or the piping leading to and from the heat pump compressor, and/or directly to the external structure of the heat pump wherein the heat pump's outdoor coil traverses. The term “heat pump coil region” as used herein refers to any of the piping around the heat pump compressor, and/or the long coil that traverses each side of the heat pump's cage-like housing, and/or the radiator-like housing that the long coil traverses within each side of the heat pump's cage-like housing. One possible use of the present invention is to use the sun light collected in a system of the present invention to evaporate a fluid from a liquid to a gas state, maintain sufficient temperature to keep all or some of fluid in the gas state as it moves toward a location where heat is beneficial such as e.g. the heat pump coil region, and then pass this fluid through a heat exchanger such as e.g. in the heat pump coil region where it condenses; after condensing to a liquid, the fluid moves back toward the solar energy collection for evaporation, thus repeating the cycle. While changing state from a vapor to a liquid in the heat exchanger, the fluid provides substantial heating known as the “latent heat of formation”, equal to the latent heat given up by the fluid during the condensation process of the fluid from a gas to a liquid state to e.g. the heat pump coil region during the condensation process to a liquid. The liquid then returns to the solar light/solar heat energy collection parts of the present invention, for vaporization to a gas, thus repeating the cycle over and over again for substantial daily heat for exchange to e.g. the heat pump coil region. The substantial heat provided by the solar collectors of the present invention can thus raise the source temperature to e.g. the heat pump outdoor coil region above the normal ambient source air temperature to the conventional heat pump outdoor coil region; from the well-known effect of source temperature on energy efficiency of a heat pump (Coefficient of Performance), it is thus observed that the highly useful thermodynamic energy provided by the solar collectors of the present invention can be very useful for improving the energy efficiency of a conventional air source heat pump, using a free and renewable source of energy of sunlight to provide the thermal energy. It is also well-known that the discharge temperature at the interior heating coil for the home, inside the air-handling unit, is a function of the source temperature to the outdoor coil; higher source temperatures enable the heat pump to provide higher discharge temperatures to the interior heating coil in the air-handling unit. Greater interior temperatures can thus be achieved with the higher source temperatures to the outdoor coil provided by the solar collectors of the present invention, thus providing improved heating performance/greater indoor comfort. Additionally, greater discharge temperatures by the heat pump to the indoor air coil enable the interior air to warm at a faster rate; this enables the heat pump to achieve a given interior thermostat setting at a faster rate, and thus enables the heat pump to operate for a lower percentage of time. For example, the greater discharge temperatures provided by the heat pump by using the methods of the present invention could enable a heat pump to operate at e.g. 50% on/50% off during e.g. certain hours of the day with favorable sunlight compared to e.g. 75% on/25% off during the same conditions but without the benefit of the present invention. Electrical energy savings are then directly related to the decrease in percentage of time that the heat pump has to operate in the electrified “on” state of the present invention compared to the conventional system. It is also well-known that below certain ambient temperatures at the outdoor coil, that “flooded” conditions exist with the refrigerant flowing through the heat pump pipes and coils. Flooded conditions means that the refrigerant exists as a 2-phase system (partially vapor and partially liquid). In order to extract maximum heat from the refrigerant for interior heating, the refrigerant must completely vaporize in the outdoor coil; however below certain ambient temperatures this does not occur in conventional air-source heat pumps, resulting in these flooded conditions of partial vapor and partial liquid phase and a reduction in the available heat output of the heat pump. Another potential advantage of the present invention is therefore to provide sufficient heat, utilizing one or more of the solar collectors of the present invention, to increase the temperature at the outdoor heat pump coil region to vaporize the refrigerant in the outdoor coil as completely as possible for as much of the day as possible, thus maximizing useful energy extraction from the refrigerant at the indoor coil/air handling unit. Avoiding flooded conditions is also beneficial to the mechanical longevity of the compressor by avoiding 2-phase (liquid and vapor) passing through the compressor that is known to cause premature wear on the compressor.

### BRIEF DESCRIPTION OF DRAWINGS

FIG. 1 shows a front view of an example of the porous metal absorber plate of the present invention. Reference numeral 1 is pointing to examples of strands of metal that are substantially inter-connected such that they form a singular object of the rectangle represented by Reference numeral 3, with an open lattice-work of air pores such as those pointed to by Reference numeral 2.

FIG. 2 shows a close-up view of an example of the porous metal absorber plate of the present invention, wherein the metal strands are labeled as Reference 1, and the air pores labeled as Reference 2, of the porous metal absorber plate. As another reference to the porous absorber plate of the present invention, FIG. 24 is a digital picture that shows Reference 1 pointing to an example of a metal strand of the porous absorber plate that is copper in this example, and Reference 2 pointing to an air pore in the open lattice work which appears white in color due to the background behind the porous metal absorber plate being white at the location of Reference point 2, and Reference 3 refers to the singular object that is an example of the porous metal absorber plate of the present invention that comprises of substantially inter-connected strands of metal to form the singular object and an open lattice work of air pores in-between the strands of metal.

FIG. 3 shows a top and side view of a 3-dimensional porous metal absorber plate of the present invention as a singular object, with depth indicated by Reference 1, length indicated by Reference 2, width indicated by Reference 3, and an example of the substantially inter-connected metal strands that form the singular 3-dimensional porous metal absorber plate with air porosity in between the metal strands indicated by Reference 4, and Reference 5 referring to the singular 3-dimensional object that is an example of the porous metal absorber plate of the present invention.

FIG. 4 shows a top and side view of an example of a working fluid being passed directly into one side and exiting out the other side of a 3-dimensional porous metal absorber plate example of the present invention, with Reference 1 showing the inlet for the working fluid, Reference 2 showing the exit of the working fluid, and Reference 3 showing an example of a singular 3-dimensional object that is an example of the porous metal absorber plate of the present invention.

FIG. 5 shows a side view of an example of a porous metal absorber plate of the present invention with pipes inserted inside the porous metal absorber plate, at a location within the depth of the porous metal absorber plate. Reference 1 refers to a pipe, Reference 2 refers to the strands of metal that are substantially inter-connected to form the singular object that is an example of the porous metal absorber plate of the present invention that is labeled as Reference 3.

FIG. 6 shows a side view of an example of a housing for the porous metal absorber plate of the present invention that utilizes transparent front and back cover glazings represented by reference numerals 3 and 4 respectively, where the convention used herein is to label the front cover glazing as the cover glazing that is closer to the sun compared to the back cover glazing, and Reference 1 shows the incident solar light that hits the front cover glazing directly, and Reference 2 shows solar light that misses the front cover glazing but then hits a plate of Reference 6 that is capable of reflecting solar light to the back of the solar collector as shown with Reference 5.

FIG. 7 shows a side view of an example of a housing for the porous metal absorber plate of the present invention that uses a double front cover glazing and double back cover glazing designated as Reference 3, 5 and References 4, 6 respectively, and wherein the space between the double glazings is either evacuated or filled with an inert gas in the space designated as Reference 1 and 2.

FIG. 8 shows a 3-dimensional top and side view of an example of the evacuated or inert gas filed glazings of the present invention that can be removed and are therefore easily replaced, and wherein Reference 2 refers to the walls of the glazing, and Reference 1 refers to the gap between the walls that is either evacuated or filled with inert gas.

FIG. 9 shows a top view of a flat plate type solar collector that uses the porous metal absorber plate of the present invention and an example of cover glazings of the present invention, as seen if sliced from the middle, and wherein Reference 1 shows an example of the porous metal absorber plate of the present invention, Reference 2 and Reference 3 show chambers that are either evacuated or filled with inert gas and that would substantially match the width and length of the porous metal absorber plate, and Reference 4 refers to the housing glazings that form the front and back covers and sidewalls for the porous metal absorber plate and the evacuated or inert gas filled chambers within the housing glazings.

FIG. 10 shows an example of a glazing cover of the present invention that uses ducts around the perimeter of the housing glazings of the collector for gathering additional sunlight that misses the front face glazing and wave guiding this light to a reflector plate, and wherein Reference 1 shows the duct from a front view of the front face of the solar collector, Reference 2 refers to the front cover glazing, References 3 and 5 show the ducts from a side view, Reference 4 shows the front cover glazing from the side view, Reference 6 is solar light that misses the front cover glazing but enters the duct of Reference 1 and is reflected off of the concave shaped reflector plate of Reference 8 to hit the back cover glazing of Reference 7.

FIG. 11 shows a side view of an example of a single front and back cover glazing for the porous metal absorber plate of the present invention, as seen from a slice in the middle, and wherein Reference 1 refers to the outside wall of the front cover glazing that has a thickness that extends all of the way to the porous absorber plate shown as Reference 2, and Reference 3 refers to the outside wall of the back cover glazing that has a thickness that extends all the way to the porous absorber plate shown as Reference 2, and Reference 4 shows an inlet port for a working fluid to enter and traverse throughout the porous metal absorber plate of Reference 2, and then exiting the porous metal absorber plate at exit port labeled as Reference 5.

FIG. 12 shows a front and side view of an example of a Fresnel lens faced duct of the present invention, wherein Reference 1 refers to the duct, Reference 2 refers to a working fluid entering the duct, Reference 3 refers to the Fresnel lens faces of the duct that are partial cylinders in this example, and reference 4 refers to the working fluid exiting the duct.

FIG. 13 shows a front and side view of an example of a Fresnel lens faced duct of the present invention, wherein Reference 1 refers to the duct, Reference 2 refers to an inner conduit containing a working fluid that enters and then traverses within the duct, Reference 3 refers to the Fresnel lens faces of the duct, and Reference 4 refers to the inner conduit exiting the duct after traversing throughout the length of the duct.

FIG. 14 shows a front and side view of an example of a Fresnel lens faced duct with parabolic geometry side and back faces of the present invention, wherein Reference 1 refers to the parabolic sidewalls and back face of the duct, Reference 2 refers to an inner conduit entering the duct and traversing the length of the duct, Reference 3 refers to a solar reflective surface on the inside walls of the parabolic shaped sidewalls and back face of the duct, Reference 4 refers to the Fresnel lens faces of the duct, and Reference 5 refers to the inner conduit exiting the duct after traversing throughout the length of the duct.

FIG. 15 shows a front and side view of an example of a Fresnel lens faced duct with a solar reflective film inserted within the duct in the shape of a parabola of the present invention, wherein Reference 1 refers to the duct, Reference 2 and Reference 5 refer to the solar reflective film inserted within the duct in the shape of a parabola and placed around an inner conduit of Reference 3 that enters the duct and traverses throughout the length of the duct in-between the solar reflective film parabola and the Fresnel lens faces of the duct, and Reference 4 refers to the Fresnel lens faces of the duct, and Reference 6 refers to the inner conduit exiting the duct after traversing throughout the length of the duct.

FIG. 16 shows a front view of an example of a heat transfer system that uses the porous metal absorber solar collector of the present invention, wherein Reference 1 refers to the inlet of a working fluid into a solar collector that uses the porous metal absorber plate of the present invention, Reference 2 refers to the porous metal absorber plate solar collector of the present invention that the working fluid traverses through, and Reference 3 refers to the exit port of the working fluid from the solar collector, and Reference 4 refers to a coiled heat exchanger that is wrapped around a pipe, and Reference 5 shows that this pipe is the inlet pipe containing a refrigerant or other working fluid into a heat pump compressor, and Reference 6 is the outlet pipe containing warmed and compressed refrigerant or other working fluid exiting the heat pump compressor, and Reference 7 refers to the heat pump compressor.

FIG. 17 shows front and side views of an example of a heat transfer system that uses both a porous metal absorber solar collector and a Fresnel duct solar concentrator collector of the present invention, wherein Reference 1 refers to the inlet of a working fluid into a solar collector that uses the porous metal absorber plate of the present invention, Reference 2 refers to the porous metal absorber solar collector of the present invention that the working fluid traverses through, and Reference 3 refers to the exit port of the working fluid from the porous metal absorber solar collector that then goes into an inner conduit that traverses through a Fresnel lens faced duct of Reference 5 with parabolic side and back walls that contain a solar reflective film of Reference 4, and during heating season the fluid goes straight through a valve, labeled as Reference 6, to a heat exchanger labeled as Reference 8, to exchange heat with the pipe of Reference 9 that leads into the inlet (low pressure) side of a heat pump compressor, and Reference 10 refers to the exit of a warmed and compressed working fluid from the heat pump compressor, and Reference 11 refers to the heat pump compressor, and Reference 7 refers to the diversion of the working fluid exiting the porous absorber plate solar collector and Fresnel lens duct collector to another heat exchange application such as for hot water heating during warmer months when the heat pump is not used for heating.

FIG. 18 shows front and side views of an example of a heat transfer system that uses both a porous metal absorber plate type solar collector and a Fresnel duct solar concentrator collector of the present invention, wherein Reference 1 refers to the inlet of a working fluid into a solar collector that uses the porous metal absorber plate of the present invention, Reference 2 refers to the porous metal plate type solar collector of the present invention that the working fluid traverses through, and Reference 3 refers to the exit port of the working fluid from the porous metal plate type solar collector that then goes into an inner conduit that traverses through a Fresnel lens faced duct of Reference 6 with a solar film formed in a parabolic shape of Reference 5 that traverses the length of the Fresnel lens faced duct Reference 4, and wherein the parabolic shape and position of the solar film of Reference 5 is such that concentrated solar light from the Fresnel refractor lenses that miss the inner conduit can at least be partially redirected onto the inner conduit, and Reference 7 refers to the outlet working fluid that is in this example hot water that enters into a storage tank of Reference 8, and Reference 9 is cooler water that is then re-circulated back to the inlet of Reference 1.

FIG. 19 shows front and side views of an example of a heat transfer system that uses the Fresnel duct solar concentrator collector of the present invention, wherein Reference 1 refers to the parabolic sidewalls and back face of the duct that have an inside surface that reflects solar light, Reference 2 refers to an inner conduit entering the duct and traversing the length of the duct, Reference 3 refers to the Fresnel lens faces of the duct that are partial cylinders in this example, and Reference 4 refers to the inner conduit exiting the duct after traversing throughout the length of the duct, and Reference 5 refers to a coiled heat exchanger that is wrapped around a pipe, and Reference 6 shows that this pipe is the inlet pipe to a hot water storage tank, and Reference 7 is a hot water storage tank.

FIG. 20 shows front and side views of an example of a heat transfer system that uses the Fresnel duct solar concentrator collector of the present invention, wherein Reference 1 refers to the duct, Reference 2 refers to the Fresnel lens faces of the duct, and Reference 3 refers to an inner conduit containing working fluid traversing the length of the duct and then exiting the duct.

FIG. 21 shows front and side views of an example of a heat transfer system that uses two different sizes of the Fresnel duct solar concentrator collectors of the present invention, wherein Reference 1 refers to a larger duct, Reference 2 refers to larger Fresnel lens faces of the Reference 1 duct, and Reference 3 refers to a smaller duct with smaller Fresnel lens faces shown by Reference 4, and Reference 5 refers to an inner conduit containing working fluid traversing the length of both the larger and smaller duct and then exiting the smaller duct.

FIG. 22 shows a front view of an example of a heat transfer system that uses the porous metal absorber solar collector of the present invention for heating air, wherein Reference 1 refers to the inlet of air into a solar collector that uses the porous metal absorber plate of the present invention, Reference 2 refers to the exit port of the air from the solar collector, and Reference 3 refers to the porous metal absorber plate solar collector of the present invention.

FIG. 23 shows an example of a heat transfer system that shows a side view of an example of a glazing cover system of the present invention that uses a front cover glazing labeled as Reference 1, ducts mounted to the sides of the cover glazings that allow sunlight that misses the front cover glazing to enter the ducts labeled as References 2 and 3, and a concave shaped sunlight reflector plate labeled as Reference 4, and a back cover glazing labeled as Reference 5 that is transparent and accepts reflected sunlight from the concave shaped reflector plate of Reference 4, and a working fluid exiting the solar collector plate labeled as Reference 6, and a front view of a heat exchanger labeled as Reference 7 where the working fluid exchanges heat and then returns to the solar collector as shown by Reference 8.

FIG. 24 is a digital picture of a front view of an example of the porous metal absorber plate of the present invention, wherein Reference 1 is pointing to an example of a metal strand of the porous absorber plate that is copper in this example, and Reference 2 pointing to an air pore in the open lattice work which appears white in color due to the background behind the porous metal absorber plate being white at the location of Reference point 2, and Reference 3 refers to the singular object that is an example of the porous metal absorber plate of the present invention that comprises of substantially inter-connected strands of metal to form the singular object and an open lattice work of air pores in-between the strands of metal.

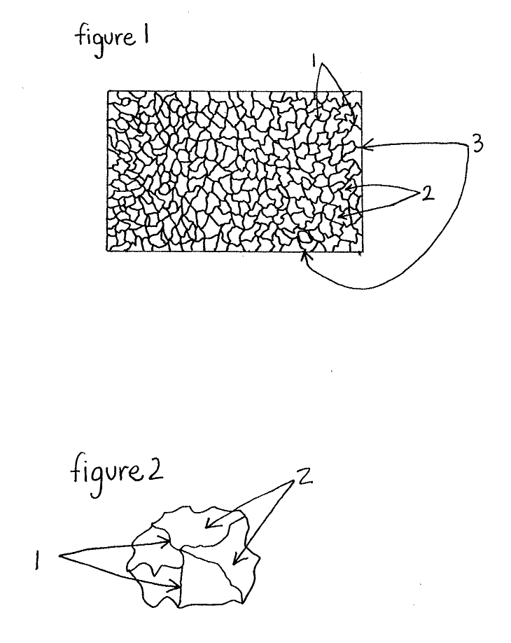

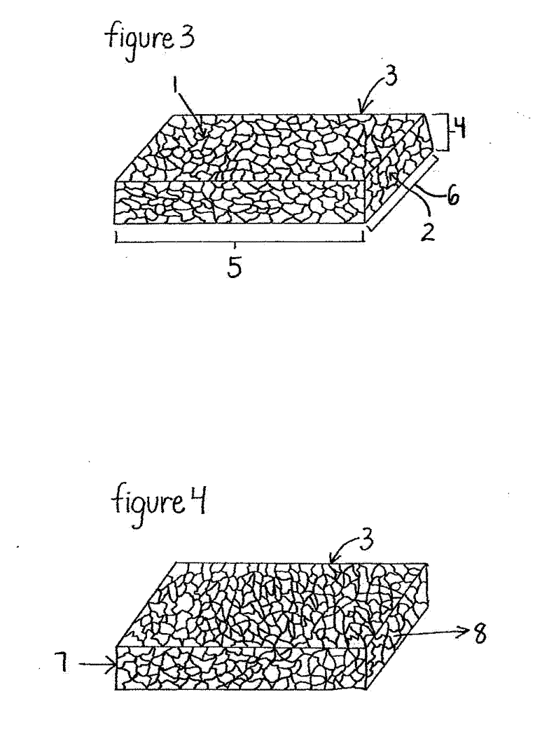

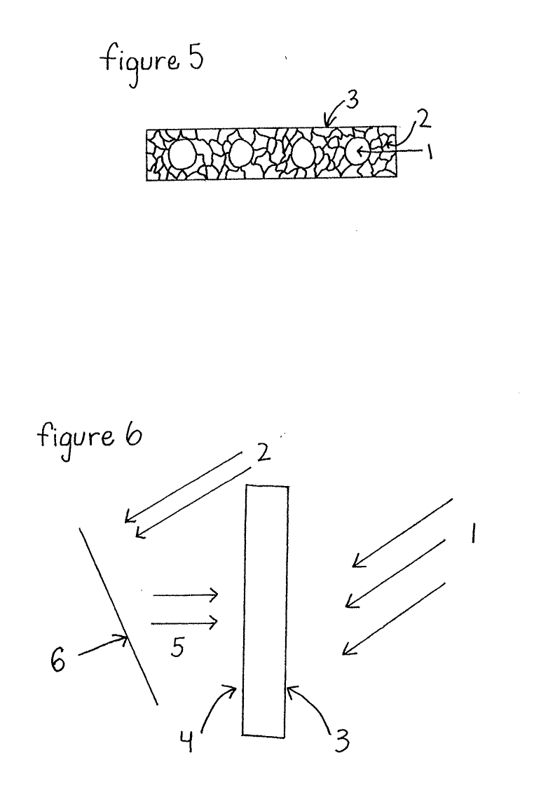

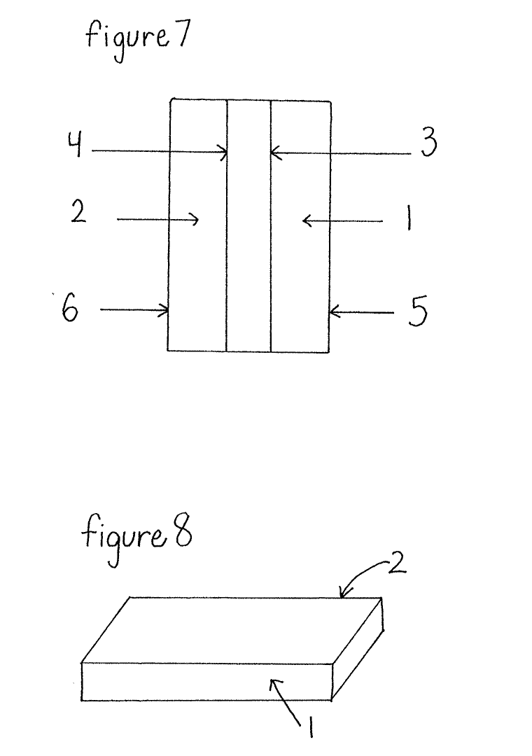

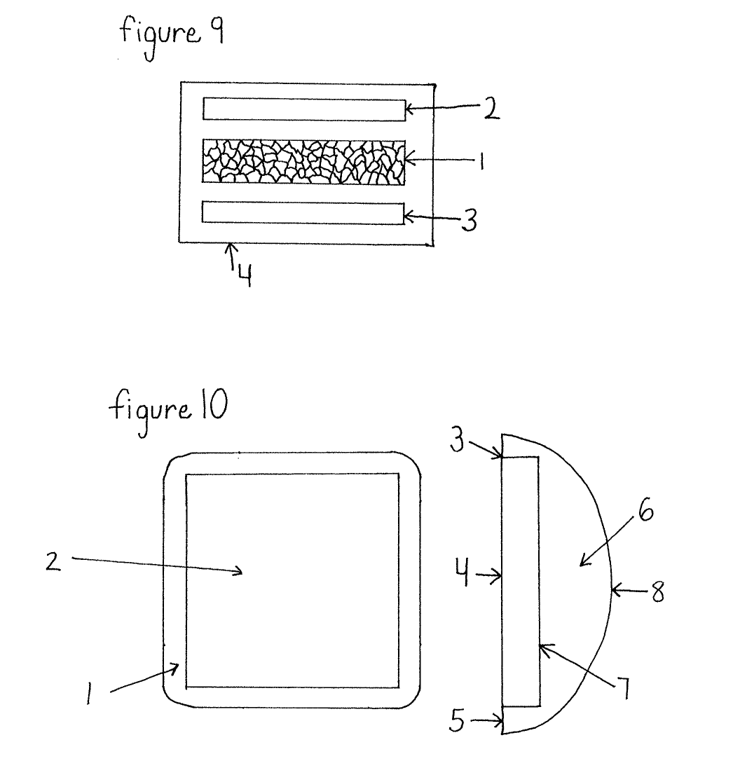

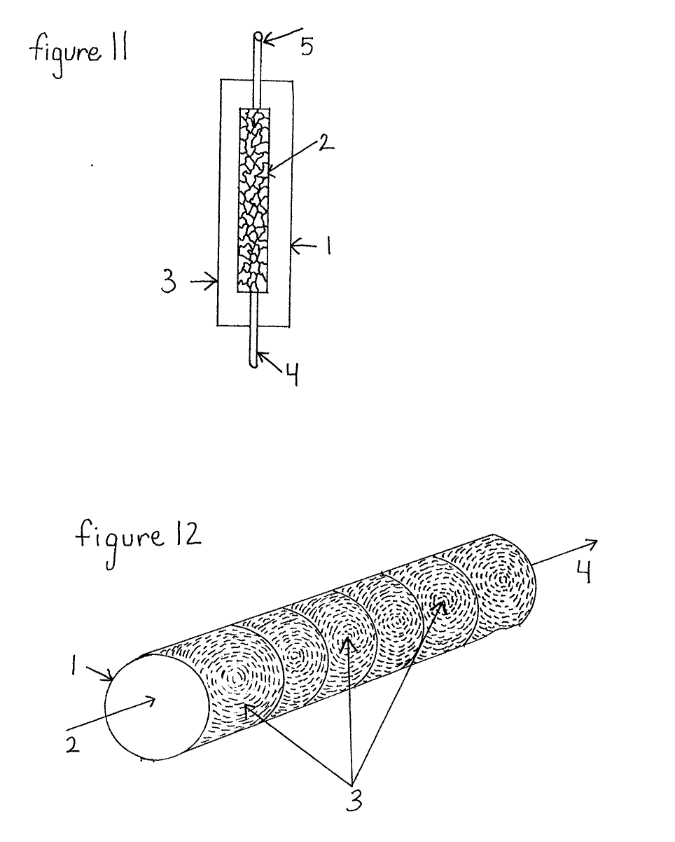

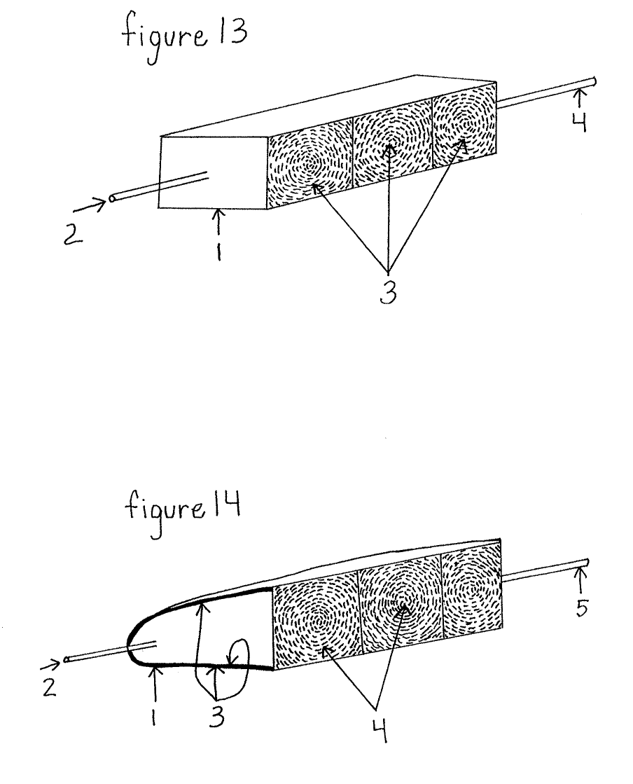

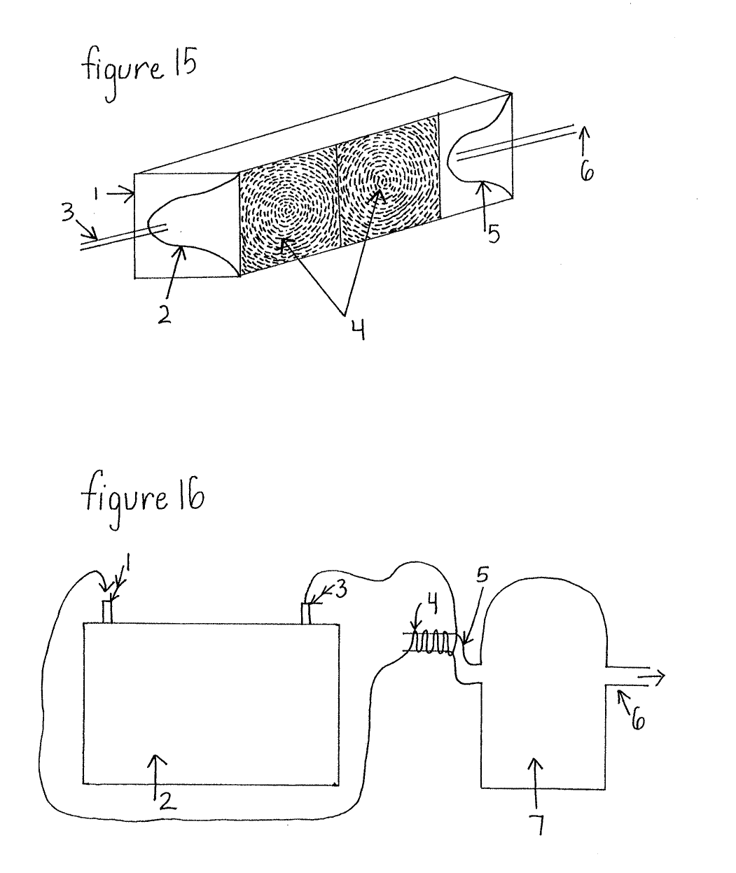

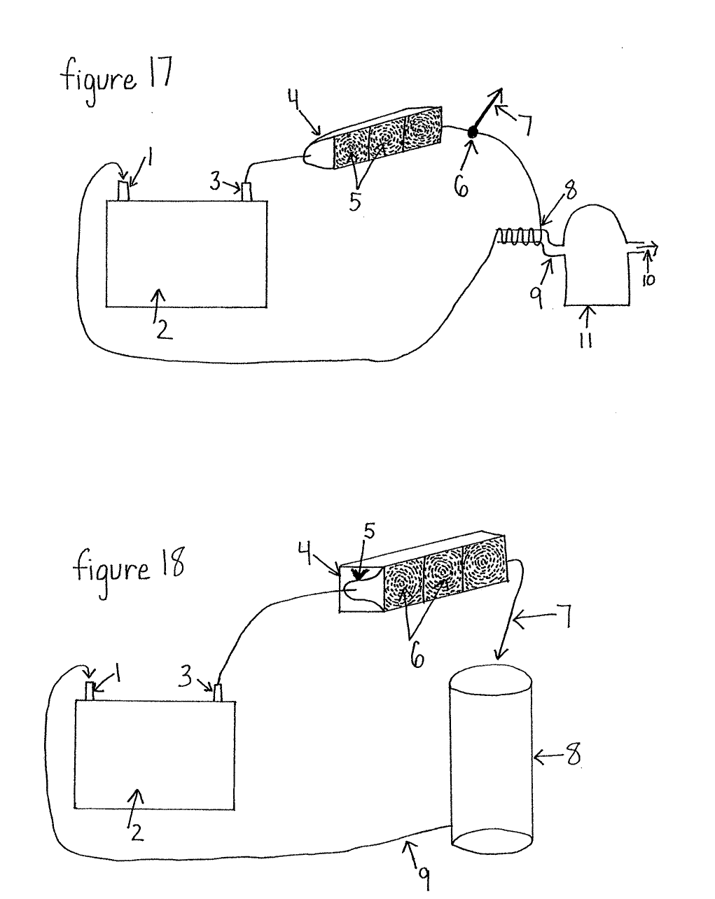

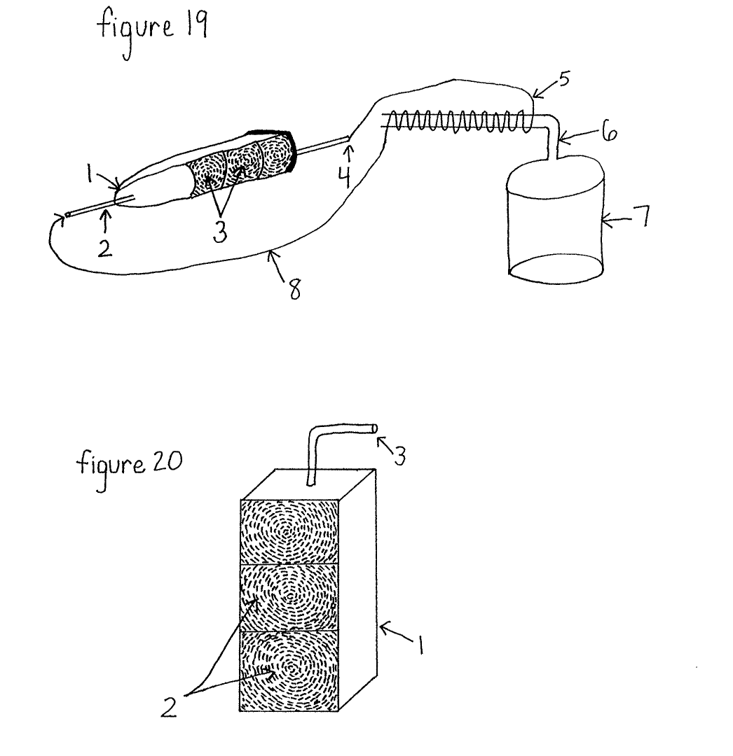

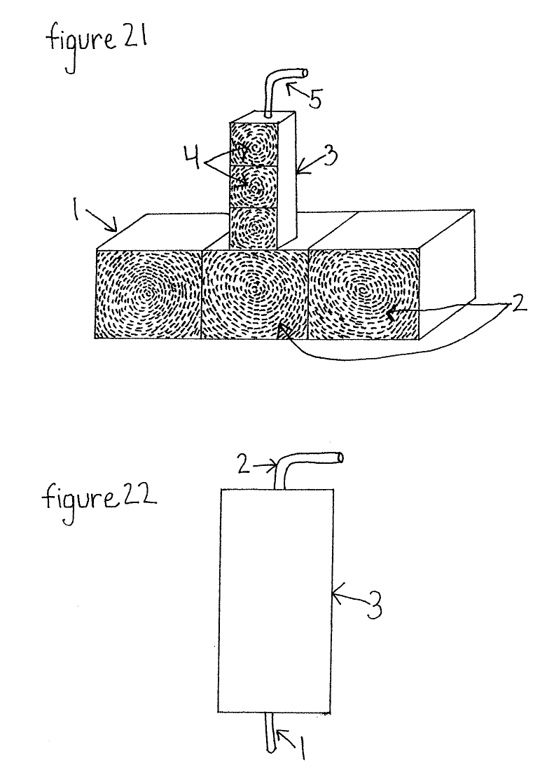

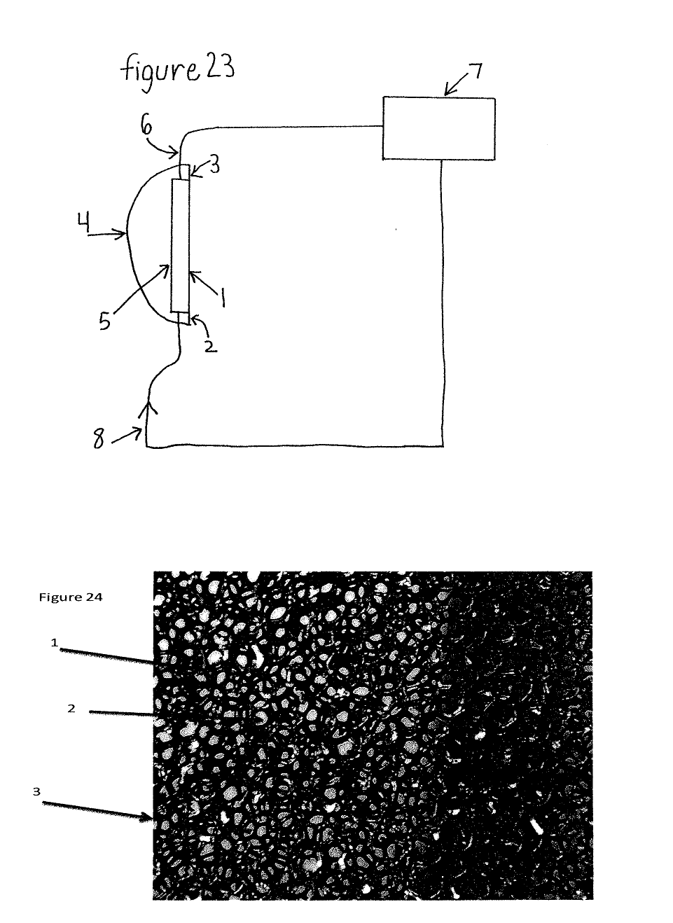

Further novel features and other advantages of the present invention will become apparent from the following description, discussion and the appended claims.

### DESCRIPTION OF EMBODIMENTS

Although specific embodiments of the present invention will now be described, it should be understood that such embodiments are by way of example only and merely illustrative of but a small number of the many possible specific embodiments which can represent applications of the principles of the present invention. Changes and modifications by persons skilled in the art to which the present invention pertains are within the spirit, scope and contemplation of the present invention as further defined in the appended claims. All references cited herein are incorporated by reference as if each had been individually incorporated.

In the porous metal absorber plate solar collector of the present invention, the porosity of the porous metal absorber plate can range from about 25% to about 98%, or from about 50% to about 98%, or from about 60% to about 98%. The pore size can range from about 0.1 mm to about 10 mm, or from about 0.1 to about 5 mm, or from about 0.1 to about 3 mm. The volume density of the porous metal absorber plate can be from about 0.1 to about 5 grams per cubic centimeter (cc), or from about 0.1 to about 2.5 grams/cc, or from about 0.1 to about 1.5 grams/cc, or from about 0.1 to about 1.1 grams/cc, or from about 0.3 to about 0.8 grams/cc, or from about 0.3 to about 0.6 grams/cc. The depth of the porous metal absorber plate can range from about 1 mm to about 100 mm, or from about 1 mm to about 50 mm, or from about 1 mm to about 25 mm, or from about 1 to about 10 mm, or from about 3 to about 6 mm. A particularly useful porous metal absorber plate of the present invention is a foamed porous metal absorber plate, and especially preferred metals for the porous metal absorber plate are selected from copper or aluminum. Silicon can also be a preferred metal, to enable the solar light penetration benefits of the porous metal absorber plate for applications in solar photovoltaic applications. For example, more solar photovoltaic production per unit front absorber plate area can be gained by using more depth of silicon of the porous metal absorber plate instead of the typical thin surface of silicon absorbing panels in photovoltaic applications; this can substantially reduce the space requirements of a solar photovoltaic system. The porous metal may be painted black, or coated with a sunlight absorbing material with chemical deposition techniques. One preferable method is to leave the metal of the porous metal absorber plate bare in order to retain the highest possible thermal conductivity of the porous metal, and instead pass a black-dyed working fluid directly through the porous metal absorber plate. The black-dyed fluid can substantially absorb solar radiant energy by acting like a black-body. The fluid can be dyed completely opaque black, or preferably to a semi-transparent or semi-translucent black such that sun light can penetrate throughout some or all of the depth of the porous metal absorber plate. The porous metal absorber plate can be used in flat-plate type solar collectors, evacuated tube type solar collectors, or any other form or type of solar energy collection apparatus.

The improved cover glazings of the present invention utilize transparent front and back faces such that solar radiant energy that misses the front face can effectively be reflected onto the back face, enabling up to twice the solar radiant energy impacting the collector per unit front-cover area of the solar collector. The improved cover glazings can further have evacuated or inert gas filled gaps between the front and/or back faces to substantially reduce convective heat transfer losses back to the environment. The improved cover glazings can further have an additional back plate with reflective surfaces such that incoming sunlight that misses the front face can be optically guided onto the back face. For example, ducts can be located along some or all of the outside perimeter of the cover glazings, and waveguide sunlight to a concave shaped wall that is covered with a suitable solar reflective film such that the sunlight that hits the concave shaped wall is reflected onto the back face of e.g. a flat plate solar collector. The improved cover glazings are preferably used with the improved porous metal absorber plate solar collectors of the present invention, forming an air or liquid-tight housing around the porous metal absorber plate of the present invention with appropriate fittings to allow a working fluid to enter and exit the porous metal absorber plate, and allowing for reflected light to hit the back transparent face of the glazing/housing to increase the solar energy absorption per unit of front face solar collector area. The cover glazings of the present invention can be made from glass clear plastics such as acrylic or polycarbonate. The cover glazing front and back faces and sidewalls can be from about 1 millimeter to about 50 mm thick, or from about 1 mm to about 25 mm thick, or from about 1 mm to about 10 mm thick, or from about 1 mm to about 6 mm thick. Stabilizing any plastic used for the cover glazings for ultra-violet light resistance is preferred. Anti-reflective or anti-abrasion coatings may also be used for the cover glazings.

The improved solar concentrating collectors of the present invention are characterized by utilizing Fresnel refracting lenses as part of an outer duct that houses a working fluid either within the duct or houses an inner conduit with working fluid inside of the inner conduit. All or a portion of the outer duct that faces the sun can be Fresnel refracting lenses, either integrally built into the duct or as inserts at various locations along the duct. The Fresnel lenses may be square, concave, hemispheres, cubes, rectangles, spheres, or cylinders for example. The Fresnel lenses can be flat-faced squares, flat-faced rectangles, flat-faced circles, concave-faced hemispheres, partial cylinders, or complete cylinders. A partial cylinder as defined herein is a portion of a full cylinder; for example, a full cylinder that is sliced in half along the length axis. Half of the length axis of the cylinder can be for example normal duct, and the other half of the length axis of the cylinder that is facing the sun can be Fresnel lenses, to form an example of a duct embodied by the present invention. The Fresnel lens or lenses of the duct can have any length or width to match the size of the duct, and can have a lens thickness from about 1 mm to about 50 mm, or from about 1 mm to about 25 mm, or from about 1 mm to about 10 mm, or from about 1 mm to about 5 mm. The focal length of the Fresnel lens can be selected to match the desired concentration factor, as well as to match the optimal length at which the e.g. inner conduit containing a working fluid is placed. The F number (focal length divided by lens diameter) can be from about 0.5 to about 2, or from about 0.5 to about 1.5, or from about 0.7 to about 1.3. The groove pitch of the Fresnel lens can be from about 0.1 mm to about 10 mm, or from about 0.1 mm to about 5 mm, or from about 0.1 mm to about 3 mm, or from about 0.1 to about 1 mm. Fresnel lenses with different properties can be used in the same system; for example, some portions of the duct can have different diameter of Fresnel lenses and different duct diameters; this enables different concentration ratios as the concentration ratio can increase with larger Fresnel lenses. Alternatively, different F number lenses can be used in the same duct, to provide different concentration values at different locations in the duct. The duct can be made from any suitable material that can handle the desired temperature and pressures within the duct, and can be in any shape that allows one or more Fresnel lenses to comprise some portion of the duct. The non-Fresnel lens inside faces or inner sides of the duct can be covered with a solar reflective material. A particularly preferred configuration of the duct is to make at least part of the interior of the duct to have a solar light reflective surface that is formed in the shape of a parabolic trough. The parabolic trough inside reflective surface can be made such that stray focused light from the Fresnel lenses that does not hit a target (such as an inner conduit within the duct that contains a working fluid), can be partially or totally redirected onto the target. Alternatively, the duct can be of other geometries, and a solar reflective film can be formed in the shape of a parabolic trough and placed inside the duct, such that the solar reflective film can redirect some or all of any stray focused light from the Fresnel lens that misses a target (such as an inner conduit within the duct that contains a working fluid), back onto the target. In embodiments where an inner conduit containing a working fluid is placed inside the Fresnel lens faced duct of the present invention, the inner conduit is preferably painted black or otherwise made such that solar light can be substantially absorbed as radiant energy with low reflectance of solar light. Inner conduits made from copper or aluminum that have a black outer surface are especially preferred. Other metals or other suitable materials that can handle the temperature and pressure or chemical compatibility with the working fluid, and that have a suitable solar light absorbing surface, can be utilized as the inner conduit material.

### Example 1

A static analysis of the heat required to raise conventional non-porous flat plate collectors to increase the temperature of the flat plate, compared to an example of a porous metal absorber plate collector of the present invention is a useful illustration of some of the benefits of the porous absorber plate collector of the present invention. Example calculations for energy (heat) required to raise the temperature by 100 degrees Fahrenheit for 2 examples of the present invention porous absorber plate collector plate compared to conventional non-porous flat collector plates are shown in Table 1:

TABLE 1

| | | | | Volume | | |
|---|---|---|---|---|---|---|
| | | | | (cubic | Density | Heat (Energy) |
| Flat plate Type | Length (ft) | Width (ft) | depth (ft) | feet) | (lbs/ft³) | required (BTU) |
| non-porous copper | 3 | 1 | 0.04 | 0.12 | 555 | 613 |
| (conventional) | | | | | | |
| porous copper (present | 3 | 1 | 0.04 | 0.12 | 31.2 | 34 |
| invention example) | | | | | | |
| non-porous aluminum | 3 | 1 | 0.04 | 0.12 | 169 | 454 |
| porous aluminum (present | 3 | 1 | 0.04 | 0.12 | 31.2 | 84 |
| invention example) | | | | | | |

The static heat required is observed to be about 80 to 95% less for these examples of porous metal absorber plates of the present invention compared to conventional non-porous flat plate collectors, for raising the plates by 100 degrees Fahrenheit and calculating the heat required as material density*volume of plate*heat capacity*100 degree temperature increase. The improved energy advantage can enable the porous metal absorber plate of the present invention to achieve higher temperatures or achieve a certain temperature at a faster rate for a given collector area, compared to conventional non-porous flat plate collectors.

### Example 2

Two flat plate collectors were prepared. The collector embodiment of the present invention comprised of about 54 mm width by 57 mm long porous copper absorber plate, with a density of about 0.5 g/cc, a thickness of about 5 mm, and a porosity of about 97%. The porous copper absorber plate was spray painted with flat black high temperature paint. The absorber plate was placed inside an aluminum housing, insulated with fiberglass insulation to avoid contact with the aluminum walls, and sealed with a glass lid and silicone caulking. A small hole was drilled to insert a thermocouple probe directly inside the copper absorber plate. An identical flat plate collector was prepared, except to use standard black anodized aluminum sheet metal (non-porous) of about 1 mm thick as the absorber plate, with about a 6 mm diameter copper tube inserted under the aluminum sheet absorber plate. A thermocouple probe was inserted into the inside wall of the copper tube. The collectors were placed in the sun, and temperature versus time was recorded on a thermocouple monitor. The results are shown in Table 2:

TABLE 2

| | Temperature of | Temperature of Black |
|---|---|---|
| Time in sun | Porous Copper, | anodized non-porous |
| (Minutes) | Celsius | Aluminum, Celsius |
| Start | 6 | 4 |
| 3 | 46 | 19 |
| 5 | 51 | 27 |
| 10 | 56 | 36 |

As observed from the data, the temperature of the porous copper plate rose much faster, and to a higher value, compared to the copper tube underneath the black anodized aluminum sheet. The faster temperature increase and higher temperatures achieved with the flat-plate type collector embodiment of the present invention can enable benefits such as improved transfer rate of solar radiant energy to a working fluid.

### Example 3

An embodiment of the Fresnel lens duct concentrating-type solar collector was prepared using a duct of about 300 mm length and about 100 mm width, with 3 Fresnel flat-faced square lenses utilized side by side to form the face of the duct facing the sun. Each Fresnel lens was about 100 mm high by 100 mm wide, and about 2 mm thick, with a groove pitch of about 0.5 mm. A solar reflective film was formed in the shape of a parabola and inserted inside the duct, along the back face. A copper pipe with inside diameter of about 13 mm was painted with flat black high temperature spray paint, and inserted inside the duct in between the solar reflective film along the back face and the Fresnel lens front face. A thermocouple probe was inserted inside the copper pipe, to monitor temperature. The same flat-plate type embodiment of Example 1 with the porous copper absorber plate was used for comparison. The results over a 45 minute test with the collectors placed in the sun yielded the results shown in Table 3:

TABLE 3

| Average Temperature | Average Temperature | Maximum Temperature | Maximum Temperature |
|---|---|---|---|
| from Fresnel | from Porous Copper | from Fresnel | from Porous Copper |
| Duct Type | Flat Plate Type | Duct Type | Flat Plate Type |
| (Celsius) | (Celsius) | (Celsius) | (Celsius) |
| 78 | 59 | 89 | 67 |

As observed from Table 3, both the average temperature and the maximum obtained were higher with the Fresnel duct concentrating solar collector. The higher temperatures achieved can enable more efficient heat transfer by providing greater temperature differences between the solar collector and e.g. a working fluid, as well as provide improved opportunity to reach the boiling point of a suitable working fluid for a highly efficient evaporation and condensation heat exchange process.

### Example 4

Two identical porous metal flat plate type collectors embodied by the present invention were prepared. Both utilized porous copper absorber plates with the same physical properties of the porous copper absorber plate of example 1, except that the dimensions of each porous copper plate were 400 mm*400 mm*5 mm thick. Each plate was placed in a housing made of about 3 mm thick clear acrylic front and back faces, with about 10 mm thick clear acrylic sidewalls. Both collectors were then placed in the sun, with thermocouple probes inserted to measure the temperature of the porous copper absorber plate. On one of the collectors, sunlight was reflected onto the back side of the collector by using a solar reflective film-covered plate placed behind the collector such that the reflected sunlight was from sunlight that did not hit the front face of the collector and thus otherwise would not have been able to be absorbed as radiant energy in the collector. Over a 30 minute period in full sun, the collector with light reflection obtained an average temperature that was 8.7 degrees Celsius higher and a maximum temperature that was 10 degrees Celsius higher than the identical collector that did not have sun light reflected onto the back face. This corresponded to an energy increase of 50% on average higher, and 56% on maximum higher, for the solar collector with sunlight reflected onto the back transparent face. This demonstrates that the transparent front and back collector faces with light reflection can offer an improvement in total solar radiant energy absorption per unit front cover area of solar collector, and is especially preferred for use with the porous metal absorber plate type solar collectors of the present invention.

An example of useful work of the solar collectors of the present invention is to raise the source temperature to the heat pump outdoor coil region above the normal ambient source air temperature to the conventional heat pump outdoor coil region. The increased source temperature to the heat pump outdoor coil region can be accomplished by utilizing one or more of the collectors of the present invention to collect solar light/solar radiant energy during daylight hours in order to heat a working fluid and then transferring this heat to the heat pump coil region via a heat exchanger around one or more parts of the heat pump coil region. The heat transfer can occur in single phase such as e.g. a working fluid such as glycol liquid that is heated to higher than ambient temperature glycol liquid, or air that is heated to higher than ambient air, or a 2-phase mixture such as e.g. partial vapor liquid with partial higher than ambient liquid, or a phase change such as e.g. a liquid that is vaporized in one or more of the collectors of the present invention, then condenses to release the latent heat of condensation to the heat pump coil region. While changing state from a vapor to a liquid in the condensation heat exchanger, the fluid can provide substantial heating to the heat pump coil region during the condensation process to a liquid, using a very small amount of working fluid. The liquid then returns to the solar light/solar radiant energy collectors of the present invention for vaporization to a gas, thus repeating the cycle over and over again for substantial daily heat for exchange to the heat pump coil region. Although any of these heat transfer phases can be utilized, the evaporation/condensation loop heat transfer method provides the advantage of much smaller system size, typically requiring only ⅕^{th} to 1/10^{th} the amount of working fluid compared to a system that utilizes a liquid phase only process. This substantial heat provided by the apparatus of the present invention can thus raise the source temperature to the heat pump outdoor coil region above the normal ambient source air temperature to the conventional heat pump outdoor coil region, thus increasing the energy efficiency and/or heating performance of the heat pump.

In a preferred embodiment of the present invention, a working fluid first traverses through one or more of the porous metal plate collector(s) of the present invention for pre-heating, then traverses through one or more inner conduit(s) within a Fresnel refracting duct that contains a parabolic trough reflecting surface behind the inner conduit to impart an additional temperature increase to the working fluid. In this manner, temperature gradients for efficient driving force are achieved while minimizing heat losses to the environment, and the highest final temperature of the working fluid for maximum heat transfer driving force is achieved. This preferred method also provides the best opportunity for vaporizing a working fluid and maintaining this fluid as a vapor along axial lengths within the higher temperature Fresnel refracting duct, so that the working fluid can impart maximum energy per unit weight of working fluid during the condensation phase change heat transfer. One example of an efficient heat exchanger is soft metal pipe, such as soft copper or soft aluminum, wound as a coil around one or more parts of the heat pump coil region or other areas where heat transfer is desired such as e.g. on pipes leading into a conventional electric water heater. A metal pipe wound as a coil provides the advantages of simple installation, and ease to retrofit around existing heat pump coil region parts or other parts for heat exchange to e.g. hot water or other heat exchange applications, as well as the ability to wrap the pipe coil “counter-current” to the temperature gradients, such as e.g. wrapping the initial parts of the heat exchanger where the working fluid is hottest around the coldest part of the selected heat pump coil region part, and traversing the heat exchanger coil thereafter in the direction of warmer parts of the selected heat transfer region. Other examples of heat exchangers such as shell and tube, or pipes within pipes can be utilized. Other heat transfer methods can be to heat hot water directly in the solar collectors of the present invention for residential or commercial uses, without a separate working fluid heat exchanger; this can be preferred in locations where the potential for freezing of water in the solar collectors or piping of the present invention is not expected. One example of a useful part of the heat pump coil region to apply the heat exchange is the pipe leading to the inlet side (low pressure side when the heat pump is in heating duty) of the compressor. Applying the heat leading to the inlet side of the compressor enables a temperature boost where it is most useful for Coefficient of Performance gain such as very near to the compressor, while assisting to avoid flooded conditions where it is most useful such as very near to the compressor. In addition to the pipe leading to the inlet side of the compressor, additional refrigerant-containing pipes of the heat pump also traverse within the “cavern” created by the heat pumps outer cage-like structure. Although the pipe leading to the inlet side of the compressor is the most preferred location to provide the heat of the apparatus of the present invention, any of the pipes within this “cavern” represent excellent places to apply the heat from the heat exchanger. This is because most of these pipes can be considered “near” to the compressor, and because they are all easily accessible to retrofit a heat exchanger, and because there is more protection from wind-convection losses within the “cavern” protected by the cage-like outer heat pump structure. Insulation wrapped around any heat exchanger that uses the solar collectors and methods of the present invention helps reduce heat losses to the environment so that the extracted solar energy is applied to the heat transfer location where it is most useful.

In another embodiment, the Fresnel refractor duct of the present invention is used to focus the sunlight energy onto a vessel or pipe(s) containing a working fluid within an inner conduit within the Fresnel duct, generating sufficient temperature to vaporize the liquid to a gas or to at least substantially warm the liquid. This method provides a simple loop that does not necessarily require a pump or fan to move the working fluid; vapor will naturally rise within the inner conduit, as would lower density warm liquid working fluid. The Fresnel duct with inner conduit can then be arranged so that the rising warm working fluid can flow to a heat exchanger where the absorbed solar radiant energy can be transferred.

The porous metal plate collectors of the present invention can also be used as a source of warm air; this warm air can flow within a duct, for example the Fresnel duct of the present invention, that contains within it a conduit pipe containing a working fluid. The warm air can act as an efficient insulator by reducing temperature gradients within the Fresnel duct to minimize heat losses from e.g. an inner conduit to the duct or to the Fresnel lens faces of the duct. This configuration can also be advantageously performed counter-current; the warmest air from the solar collector placed near to the heat transfer region flows upward in the duct leading to another solar collector and/or concentrator at a location further away from the heat transfer region such as e.g. near the roof where the working fluid originated. It is thus observed that the warmest air from the warm-air solar collector will be in contact with the coldest section of the conduit pipe carrying the working fluid to the heat exchange region, resulting in maximum heat exchange efficiency. Alternatively, either the porous metal absorber plate solar collector of the present invention, or the Fresnel lens faced duct solar collector of the present invention, or both, can be utilized for heating air directly for use in e.g. interior heating applications or for other heat exchange applications with air.

For any of the embodiments, a pump and/or compressor can be used to circulate the liquid or vapor throughout the heat exchange loop. The pump and/or compressor can be electric powered with normal household electricity, or advantageously employ a solar photovoltaic cell powered pump or compressor, or advantageously use a battery (e.g. 12V) for powering a pump or compressor that is charged by a solar photovoltaic cell. A photocell or timer can be utilized so that the pump only operates during daylight hours. Thermo siphoning, gravity, and pressure gradients may also advantageously be utilized to circulate the working fluid throughout the heat exchange loop.

When the collectors and methods of the present invention are utilized to improve the energy efficiency or performance of heat pumps, a suitable method can be implemented for warm months when heat pumps are frequently used for cooling (air conditioning). The present invention can simply cover the solar collector(s) or solar concentrator(s) to avoid adding heat to the system when the heat pump is trying to reject heat to the outdoor environment when used as an air conditioner. Alternatively, valves and additional piping can be employed so that the fluid in the heat exchanger is now heated by the heat the heat pump is rejecting to the outdoor environment, combined with the high ambient temperatures when the heat pump is used for air conditioning, and sent to an underground loop where it can cool; the cool liquid then returns to the heat exchanger where it again assist the heat pump in rejecting heat to the outdoor environment, repeating the cycle over and over again to improve the cooling efficiency of the heat pump. A working fluid that evaporates in typical warm air conditions can be used to evaporate in the heat exchanger, and then condense underground, for a high efficiency heat exchange method. Alternatively, piping and valves can be installed that enable the solar energy collectors of the present invention to send a warm working fluid to e.g. a hot water heater, for efficient water heating during warm weather months.

In other embodiments, any combination of the above embodiments can be utilized together.

In some embodiments of the present invention, the average source temperature for one or more parts of the heat pump coil region is at least 1 degree Celsius higher than the normal average ambient air source temperature measured at the same part(s) of the conventional heat pump structure during a 1 hour period of peak sun light intensity time of day that also corresponds to a time of day without obstruction of sun light to the apparatus from external sources such as clouds, buildings, trees, or other forms of sun light obstruction. Under these same conditions, the average source temperature for one or more parts of the heat pump coil region can also be 2 degrees Celsius higher than the normal average ambient source air temperature to the same part(s) of the conventional heat pump structure, or 3 degrees Celsius higher, or 4 degrees Celsius higher, or 5 degrees Celsius higher, or 6 degrees Celsius higher, or 7 degrees Celsius higher, or 8 degrees Celsius higher, or 9 degrees Celsius higher, or 10 degrees Celsius or higher, or 15 degrees Celsius or higher, or 20 degrees Celsius or higher, or 30 degrees Celsius or higher, or 40 degrees Celsius or higher, or even 50 degrees Celsius or higher than the normal average ambient source air temperature to the conventional heat pump structure The increased source temperature to the heat pump coil provided by the apparatus and methods of the present invention can enable the heat pump to obtain a higher energy efficiency by achieving a higher energy output per unit of electrical energy input to the compressor, and/or enable the heat pump to deliver a higher discharge temperature to the indoor coil in the air handler to increase the rate of interior heating and decrease the percentage of time that the heat pump needs to operate per day. Alternatively, the increased source temperature to the heat pump provided by the apparatus and methods of the present invention can enable an improved heating performance by enabling a higher interior temperature at similar efficiency, i.e. at a similar Coefficient of Performance of conventional heat pump system, but obtain higher interior air temperatures. Alternatively a compromise of some gain in energy efficiency such as e.g. some gain in Coefficient of Performance with some increase in interior air temperature above the interior air temperature setting without the apparatus can be obtained. Similar performance can be expected for applying the solar collectors and methods of the present invention to ground-source heat pumps.

Other applications and alternatives are to utilize the solar radiant energy extracted by one or more solar collectors of the present invention to heat a working fluid such as water, glycol, or air; the increase in temperature provided by one or more solar collectors of the present invention to the working fluid enables the working fluid to impart useful thermal energy via heat exchange to the heat pump coil region, to a water heater, to the interior coil of other types of heating systems, to chemical production processes that require thermal energy, to lower the viscosity of industrial fluids to reduce pumping power requirements, or for a variety of other useful purposes wherein the thermal energy can be exchanged. In these or any other methods of the present invention, the useful thermal energy that is extracted from solar radiant energy can be utilized with a single-phase such as e.g. heating cool liquid water to a relatively warmer liquid water, or heating cool air to a relatively warmer air, with a 2-phase mixed system such as e.g. a cool liquid heated to a relatively warmer partial liquid and partial vapor, or a 2-phase evaporation/condensation system such as e.g. a liquid that is vaporized and maintained as a vapor for condensation phase-change heat exchange.

1. A solar energy collection apparatus comprising of: said solar energy collection apparatus comprises an absorber plate, said absorber plate comprises a porous metal, in which said porous metal comprises substantially inter-connected strands of metal, said porous metal further comprises a substantially open lattice work of air pores between said substantially inter-connected strands of metal, wherein said inter-connected strands of metal being configured to form a substantially singular object with said open lattice work of air pores, in which said porous metal further comprises a porosity of approximately 85% to 98%, and said open lattice work of air pores comprises a pore size of approximately 0.1 mm to 10 mm, said porous metal further comprises a volume density of approximately 0.1 to 1 grams per cubic centimeter (cc), [J1] wherein said porosity, pore size, and density of said porous metal is configured to enable a working fluid to substantially traverse throughout said open lattice work of air pores between said inter-connected strands of metal of said absorber plate, and said porous metal absorber plate further comprises a depth of approximately 1 mm to 100 mm, and wherein said depth of said porous metal being configured to trap light rays that penetrates said porous metal absorber plate and generally refracting and reflecting said light rays within said open lattice work of air pores between said inter-connected strands of metal of said absorber plate substantially preventing said light rays from escaping, and said porous metal absorber plate being configured to enable a working fluid to substantially traverse said open lattice work of air pores between said inter-connected strands of metal of said absorber plate as to enable substantial solar energy harvest from said solar energy collection apparatus without the use of a radiation trap structure in-between said porous metal absorber plate and any type of cover glazing of said solar energy collection apparatus

2. The solar energy collection apparatus of claim 1, in which the substantially inter-connected strands of metal of said porous metal absorber plate substantially comprise of copper, aluminum, silicon, and any combination thereof.[J2]

3. The solar energy collection apparatus of claim 1 further comprises transparent cover glazing, wherein said transparent cover glazing being configured to form a substantially sealed housing around said porous metal absorber plate, in which said cover glazing comprises at least one entrance and at least one exit being configured to enable said working fluid to enter and exit said porous metal absorber plate.

4. The transparent cover glazings of claim 3 that comprise of at least 2 cover glazings wherein a gap exists between the cover glazings, and wherein the gap is filled with an inert gas.

5. The transparent cover glazings of claim 3 that comprise of at least 2 cover glazings wherein a gap exists between the cover glazings, and wherein the gap is evacuated.

6. The transparent cover glazings of claim 3 that further comprise of a solar light transmitting duct around at least one side of the transparent cover glazings, and wherein solar light is wave-guided within the solar light transmitting duct to impact a reflective plate such that additional solar radiant energy is reflected onto the back transparent cover glazing of the solar energy collection apparatus.

7. The solar energy collection apparatus of claim 1, wherein said working fluid is passed directly through any of the length, width, and/or depth axes of said open lattice work of air pores between said inter-connected strands of metal of said porous metal absorber plate.

8. The solar energy collection apparatus of claim, in which said working fluid comprises black-dyed working fluid, wherein said black-dyed working fluid being configured to traverse said open lattice work of air pores between said inter-connected strands of metal of said porous metal absorber plate and to generally absorb solar radiant energy.

9. The solar energy collection apparatus of claim 1, wherein at least a portion of the porous metal absorber plate is substantially coated with a solar light absorbing coating.

10. Solar energy collection apparatus wherein Fresnel refractor lenses are utilized at least as part of the face of a duct facing the sun.

11. The solar energy collection apparatus of claim 10 wherein a working fluid is contained within at least one inner conduit that traverses within the Fresnel refracting lens faced duct.

12. The solar energy collection apparatus of claim 10 wherein the Fresnel lens faces are in shapes selected from the group flat-faced squares, flat-faced rectangles, flat-faced circles, concave-faced hemispheres, cubes, rectangles, spheres, partial cylinders, and complete cylinders.

13. Solar energy collection apparatus wherein Fresnel refractor lenses are utilized at least as part of the face of the duct facing the sun, and wherein at least part of the interior of the duct has a solar light reflective surface that is formed in the shape of a parabolic trough.

14. The solar energy collection apparatus of claim 13 wherein a working fluid is contained within at least one inner conduit that traverses within the Fresnel refracting lens faced duct.

15. The solar energy collection apparatus of claim 13 wherein the Fresnel lens faces are in shapes selected from the group flat-faced squares, flat-faced rectangles, flat-faced circles, concave-faced hemispheres, cubes, rectangles, spheres, partial cylinders, and complete cylinders.

16. The use of the solar energy collection apparatus of claim 10 for achieving a temperature increase in a working fluid within the Fresnel refractor lens faced duct for the purpose of reducing the viscosity of the working fluid within the duct.

17. The use of the solar energy collection apparatus of claim 13 for achieving a temperature increase in a working fluid within the Fresnel refractor lens faced duct for the purpose of reducing the viscosity of the working fluid within the duct.

18. The use of the solar energy collection apparatus of claim 1 for achieving a temperature increase in a working fluid, and the working fluid is then used to transfer heat to a heat sink selected from the group consisting of a heat pump, an indoor coil, a heat exchanger, a tank, and radiator.

19. The solar energy collection apparatus of claim 1, wherein said apparatus being configured for directly heating water.

20. The solar energy collection apparatus of claim 1, wherein said apparatus being configured for directly heating air.

21. The solar energy collection apparatus of claim 2, wherein said apparatus is configured to operate suitably for solar photovoltaic electric generation.

22. The solar energy collection apparatus of claim 1, wherein said apparatus being configured as a solar energy vessel for industrial processes

23. The use of the solar energy collection apparatus of claim 10 for achieving a temperature increase in a working fluid, and the working fluid is then used to transfer heat to a heat sink selected from the group consisting of a heat pump, an indoor coil, a heat exchanger, a tank, and radiator.

24. The use of the solar energy collection apparatus of claim 10 for directly heating water.

25. The use of the solar energy collection apparatus of claim 10 for directly heating air.

26. The use of the solar energy collection apparatus of claim 13 for achieving a temperature increase in a working fluid, and the working fluid is then used to transfer heat to a heat sink selected from the group consisting of a heat pump, an indoor coil, a heat exchanger, a tank, and radiator.

27. The use of the solar energy collection apparatus of claim 13 for directly heating water.

28. The use of the solar energy collection apparatus of claim 13 for directly heating air.
